(19) United States
(12) Patent Application Publication
(10) Pub. No.: US 2019/0388799 A1
(43) Pub. Date: Dec. 26, 2019

(54) Waste Gas Processing Device, Vacuum Coating System, and Operation Method of Waste Gas Processing Device

(71) Applicant: Dongtai Hi-Tech Equipment Technology Co., Ltd, Beijing (CN)

(72) Inventors: Ji NING, Beijing (CN); Xinyun ZHANG, Beijing (CN); Yunling PANG, Beijing (CN); Qingsong ZHAO, Beijing (CN)

(21) Appl. No.: 16/174,314

(22) Filed: Oct. 30, 2018

(30) Foreign Application Priority Data
Jun. 21, 2018 (CN) 201810644110.X

(51) Int. Cl. B01D 8/00; C23C 14/24

(52) U.S. Cl. CPC B01D 8/00; C23C 14/24

(57) ABSTRACT

Provided are a waste gas processing device, a vacuum coating system, and an operation method of the waste gas processing device. The waste gas processing device is configured to remove and recover arsenic in the waste gas, and includes a condensation portion and a scraping portion. The condensation portion is provided with a condensation cavity, and an air inlet, an air outlet and a discharge port communicated with the condensation cavity. A partial surface of the scraping portion abutting against an inner wall surface of the condensation cavity. The present disclosure solves a problem in a conventional art that an economic cost of a waste gas processing device is too high during the removal and recovery of arsenic in waste gas.

The present application claims benefit of Chinese Patent Application No. 201810644110.X, filed on Jun. 21, 2018 and entitled “Waste gas processing device, vacuum coating system, and operation method of waste gas processing device”, the contents of which are hereby incorporated by reference in its entirety.

### TECHNICAL FIELD

The present disclosure relates to a technical field of waste gas processing, and in particular to a waste gas processing device, a vacuum coating system, and an operation method of the waste gas processing device.

### BACKGROUND

A waste gas generated by a vacuum coating machine contains arsenic. If the arsenic in the waste gas is directly discharged into an external environment, the environment will be polluted, and a physical health of people will be harmed.

In a related art, in order to solve a technical problem, the waste gas is usually sprayed by a strong oxidant water solution, and arsenic in the waste gas is separated and collected in a manner of adding a high speed centrifugation device. This solution needs to consume a chemical reagent so as to cause a higher economic cost for waste gas processing. In addition, this solution may also generate waste water and water-containing waste gas, so as to increase subsequent waste gas processing steps, thereby increasing the economic cost for waste gas processing.

### SUMMARY

Some embodiments of the present disclosure provide a waste gas processing device, a vacuum coating system, and an operation method of the waste gas processing device, intended to solve a problem in a related art that an economic cost of the waste gas processing device is too high during the removal and recovery of arsenic in waste gas.

In order to achieve the foregoing objective, according to an aspect of some embodiments of the present disclosure, the waste gas processing device is provided for removing and recovering arsenic in the waste gas. The waste gas processing device includes: a condensation portion, the condensation portion being provided with a condensation cavity, and an air inlet communicated with the condensation cavity, an air outlet communicated with the condensation cavity and a discharge port communicated with the condensation cavity, the condensation portion being configured to cool the waste gas charged into the condensation cavity from the air inlet, so that gaseous arsenic in the waste gas is condensed on an inner wall surface of the condensation cavity by cooling to form solid arsenic; and a scraping portion, the scraping portion being rotatably provided in the condensation cavity, a partial surface of the scraping portion abutting against the inner wall surface of the condensation cavity, the scraping portion rotating to scrape off the solid arsenic condensed on the inner wall surface of the condensation cavity, and a scraped-off solid arsenic being discharged from the discharge port.

In an exemplary embodiment, the condensation cavity is cylindrical, the scraping portion is a scraping plate, a length of the scraping plate is equal to a diameter or a radius of the condensation cavity, a thickness of the scraping plate is equal to a height of the condensation cavity, and at least one breather hole is provided on the scraping plate.

In an exemplary embodiment, the discharge port is located at a bottom of the condensation portion in a vertical direction.

In an exemplary embodiment, the condensation portion also has an overflow cavity, a liquid inlet and a liquid outlet, wherein the overflow cavity and the condensation cavity are provided at an interval, both the liquid inlet and the liquid outlet are communicated with the overflow cavity, and a coolant flows through the liquid inlet, the overflow cavity and the liquid outlet in sequence to control an internal temperature of the condensation cavity.

In an exemplary embodiment, the condensation portion includes: a barrel; and two cover plates, the two cover plates covering two ends of the barrel respectively, wherein the condensation cavity is surrounded by the two cover plates and the barrel, the overflow cavity being formed on the barrel and/or at least one cover plate.

In an exemplary embodiment, an mounting hole is provided on at least one cover plate, the waste gas processing device further includes a driving portion, and the driving portion includes: a housing, one end of the housing being connected with the condensation portion and located at the mounting hole; a driving member, the driving member being provided at the other end of the housing and connected to the scraping portion through a driving shaft penetrating into the housing; and a bearing, the bearing being installed in the housing, and two ends of the driving shaft being provided with one bearing separately.

In an exemplary embodiment, the waste gas processing device further includes a sealing flange, the housing being connected with at least one cover plate through the sealing flange, and a magnetic fluid for sealing being provided between the housing and the driving shaft.

According to another embodiment of the present disclosure, a vacuum coating system is provided. The vacuum coating system includes: a vacuum coating machine, the vacuum coating machine being provided with a waste gas discharge outlet; and a waste gas processing device, an air inlet of the waste gas processing device being communicated with the waste gas discharge outlet, the waste gas processing device being the foregoing waste gas processing device.

According to another embodiment of the present disclosure, an operation method of a waste gas processing device is provided for operating the foregoing waste gas processing device. The method includes the following steps. In step S1, a temperature of a condensation cavity of a condensation portion is controlled to be lower than a freezing point of arsenic. In step S2, waste gas is charged into the condensation cavity from an air inlet of the condensation portion, so that gaseous arsenic in the waste gas comes into contact with an inner wall surface of the condensation cavity and is condensed on the inner wall surface of the condensation cavity to form solid arsenic. In step S3, a driving portion of the waste gas processing device is controlled to be started to drive a scraping portion to rotate, the scraping portion rotates to scrape off the solid arsenic condensed on the inner wall surface of the condensation cavity, and then the solid arsenic is discharged from a discharge port of the condensation portion.

By applying the technical solution of the present disclosure, a condensation portion has a condensation cavity and an air inlet communicated with the condensation cavity and an air outlet communicated with the condensation cavity, a waste gas is charged into the condensation cavity from the air inlet, the condensation portion cools the waste gas to make gaseous arsenic in the waste gas condensed on an inner wall surface of the condensation cavity to form solid arsenic, a scraping portion then rotates to scrape the solid arsenic off, the scraped-off solid arsenic is discharged out of the condensation cavity from a discharge port under an action of gravity, and the waste gas without arsenic is discharged out of the condensation cavity from the air outlet. The waste gas processing device provided in the present application is simple in structure and low in economic cost, and can effectively remove and recover arsenic in the waste gas.

### BRIEF DESCRIPTION OF THE DRAWINGS

The accompanying drawings, which constitute a part of this application, are used to provide a further understanding of the present disclosure, and the exemplary embodiments of the present disclosure and the description thereof are used to explain the present disclosure, but do not constitute improper limitations to the present disclosure. In the drawings:

FIG. 1 illustrates a structural schematic diagram of a waste gas processing device according to an alternative embodiment of the present disclosure; and

FIG. 2 illustrates a partial section schematic diagram of the waste gas processing device in FIG. 1.

The drawings include the following reference signs:

10: condensation portion; 11: condensation cavity; 12: air inlet; 13: air outlet; 14: discharge port; 15: overflow cavity; 16: barrel; 17: cover plate; 171: mounting hole; 20: scraping portion; 21: breather hole; 30: driving portion; 31: housing; 32: driving member; 33: bearing; 34: driving shaft; 40: sealing flange; 50: magnetic fluid.

### DETAILED DESCRIPTION OF THE EMBODIMENTS

The technical solutions in the embodiments of the present disclosure will be clearly and completely described here in below with the drawings in the embodiments of the present disclosure. It is apparent that the described embodiments are part of the embodiments of the present disclosure, not all of the embodiments. The following description of at least one exemplary embodiment is only illustrative actually, and is not used as any limitation for the present disclosure and the application or use thereof. On the basis of the embodiments of the present disclosure, all other embodiments obtained on the premise of no creative work of those of ordinary skill in the art fall within the scope of protection of the present disclosure.

In order to solve a problem in a related art that an economic cost of the waste gas processing device is too high during the removal and recovery of arsenic in waste gas, an embodiment of the present disclosure provides a waste gas processing device, a vacuum coating system, and an operation method of the waste gas processing device, wherein the vacuum coating system includes the foregoing and following waste gas processing device, and the operation method of the waste gas processing device is used for operating the foregoing and following waste gas processing device.

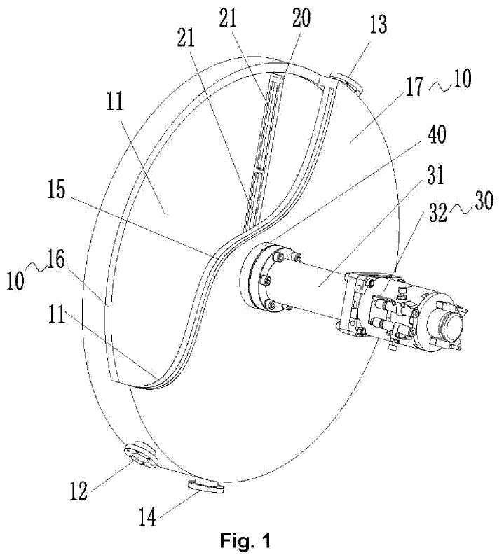

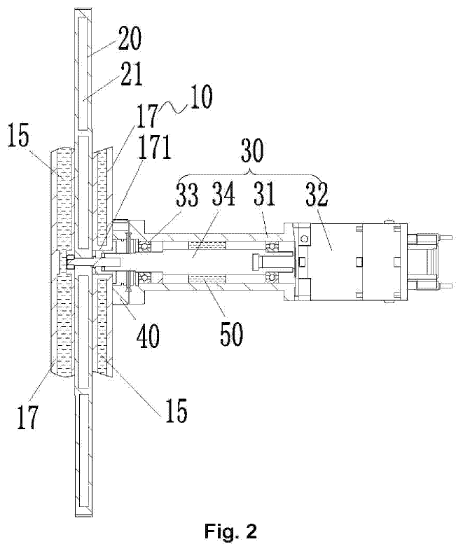

As shown in FIG. 1 and FIG. 2, the waste gas processing device for removing and recovering arsenic in waste gas includes a condensation portion 10 and a scraping portion 20. The condensation portion 10 is provided with a condensation cavity 11, and an <air inlet 12 communicated with the condensation cavity 11, an air outlet 13 communicated with the condensation cavity 11 and a discharge port 14 communicated with the condensation cavity 11. The condensation portion 10 is configured to cool the waste gas charged into the condensation cavity 11 from the air inlet 12, so that gaseous arsenic in the waste gas is condensed on an inner wall surface of the condensation cavity 11 by cooling to form solid arsenic. The scraping portion 20 is rotatably provided in the, condensation cavity 11, and a partial surface of the scraping portion 20 abuts against the inner wall surface of the condensation cavity 11. The scraping portion 20 rotates to scrape off the solid arsenic condensed on the inner wall surface of the condensation cavity 11, and the scraped-off solid arsenic is discharged from the discharge port 14.

In the embodiment of the present disclosure, the condensation portion 10 is provided with the condensation cavity 11 and the air inlet 12 and the air outlet 13 communicated with the condensation cavity 11, waste gas is charged into the condensation cavity 11 from the air inlet 12, the condensation portion 10 cools the waste gas to make the gaseous arsenic in the waste gas condensed on the inner wall surface of the condensation cavity 11 to form the solid arsenic, the scraping portion 20 then rotates to scrape the solid arsenic off, the scraped-off solid arsenic is discharged out of the condensation cavity 11 from the discharge port 14 under an action of gravity, and the waste gas without arsenic is discharged out of the condensation cavity 11 from the air outlet 13. The waste gas processing device provided in the embodiment is simple in structure and low in economic cost, and can effectively remove and recover arsenic in the waste gas.

In addition, compared with the waste gas processing device in the related art, the waste gas processing device provided in some embodiments of the present application adopts a physical method, does not need a chemical reagent, and will not generate the waste water and water-containing waste gas, so as to reduce the economic cost of the waste gas processing device. The solid arsenic condensed on the inner wall surface of the condensation cavity 11 is recovered by the scraping portion 20. Compared with a technical solution of recovering arsenic by a high speed centrifugation device in the related art, the embodiment of the present application has characteristics of simple structure and convenient operation.

In an exemplary embodiment, an internal temperature of the condensation cavity 11 is controlled to be lower than a freezing point of arsenic, so that the gaseous arsenic in the waste gas is condensed into sheet-like solid arsenic attached to the inner wall of the condensation cavity 11.

In an exemplary embodiment, as shown in FIG. 1, the condensation cavity 11 is cylindrical, the scraping portion 20 is a scraping plate, a length of the scraping plate is equal to a diameter or radius of the condensation cavity 11, a thickness of the scraping plate is equal to a height of the condensation cavity 11, and at least one breather hole 21 is provided on the scraping plate. Thus, the scraping plate is controlled to rotate, and the surfaces of two ends in a thickness direction of the scraping plate and a surface, abutting against the inner wall surface of the condensation cavity 11, in a length direction of the scraping plate scrape off the solid arsenic condensed on the inner wall surface of the condensation cavity 11. In an exemplary embodiment, at least one breather hole 21 is provided on the scraping plate, the waste gas can flow at both sides of the scraping plate from the breather hole 21, and the scraped-off solid arsenic can also penetrate through the breather hole 21 under the action of gravity to directly fall into the discharge port 14 or fall down to the discharge port 14.

As shown in FIG. 1, the discharge port 14 is located at a bottom of the condensation portion 10 in a vertical direction. Thus, the scraped-off solid arsenic can be gathered toward the bottom of the condensation portion 10 under the action of gravity, and is smoothly discharged out of the condensation cavity 11 from the discharge port 14 under the action of gravity.

As shown in FIG. 1 and FIG. 2, the condensation portion 10 also includes an overflow cavity 15, a liquid inlet and a liquid outlet, wherein the overflow cavity 15 and the condensation cavity 11 are provided at an interval, both the liquid inlet and the liquid outlet are communicated with the overflow cavity 15, and a coolant flows through the liquid inlet, the overflow cavity 15 and the liquid outlet in sequence to control an internal temperature of the condensation cavity 11. Thus, the coolant is circularly charged into the overflow cavity 15 so as to control the internal temperature of the condensation cavity 11, thereby cooling the waste gas in the condensation cavity 11.

As shown in FIG. 1, the condensation portion 10 includes a barrel 16 and two cover plates 17. The two cover plates 17 cover two ends of the barrel 16 respectively, the condensation cavity 11 is surrounded by the two cover plates 17 and the barrel 16, and the overflow cavity 15 is formed on the barrel 16 and/or at least one cover plate 17.

In an alternative embodiment of FIG. 1, the air inlet 12, the air outlet 13 and the discharge port 14 are provided on the barrel 16 at intervals, the air inlet 12 and the air outlet 13 are provided oppositely, and the discharge port 14 is closer to the air inlet 12 than the air outlet 13. During use, the discharge port 14 is located at the bottom of the barrel 16 in a vertical direction, so that the scraped-off solid arsenic can be smoothly discharged from the discharge port 14 under the action of gravity. During a process of flowing from the air inlet 12 to the air outlet 13, the waste gas is in full contact with the inner wall of the condensation cavity 11. Since the internal temperature of the condensation cavity 11 is lower than the freezing point of arsenic, the gaseous arsenic in the waste gas is condensed into the sheet-like solid arsenic attached to the inner wall of the condensation cavity 11.

Alternatively, the air inlet 12 is provided with an air inlet flange, the air outlet 13 is provided with an air outlet flange, and the discharge port 14 is provided with a discharge flange. Thus, the waste gas processing device can be conveniently connected with other devices by the flanges.

Alternatively, an included angle between the air inlet 12 and the air outlet 13 is greater than or equal to 170° and is smaller than or equal to 190°, and an included angle between the air inlet 12 and the discharge port 14 is greater than or equal to 15° and is smaller than or equal to 45°.

In an exemplary embodiment, the included angle between the air inlet 12 and the air outlet 13 is 180°. Thus, it is convenient for the waste gas to enter the condensation cavity 11 from the air inlet 12 and to be discharged out of the condensation cavity 11 from the air outlet 13. The included angle between the air inlet 12 and the discharge port 14 is 30°. Thus, an installation space is reserved for providing the air inlet flange, the air outlet flange and the discharge flange.

Alternatively, there is a plurality of air inlets 12 and/or air outlets 13, wherein a number of the air inlet 12 is equal to or different from a number of the air outlet 13.

In a non-illustrated embodiment of the present application, one cover plate 17 is provided with the air inlet 12 and the discharge port 14 provided at an interval, and another cover plate 17 is provided with the air outlet 13.

In an exemplary embodiment, as shown in FIG. 1 and FIG. 2, an mounting hole 171 is provided on at least one cover plate 17, the waste gas processing device includes a driving portion 30, and the driving portion 30 includes a housing 31, a driving member 32, a bearing 33, and a driving shaft 34, wherein one end of the housing 31 is connected with the condensation portion 10 and located at the mounting hole 171; the driving member 32 is provided at the other end of the housing 31 and connected to the scraping portion 20 through the driving shaft 34 penetrating into the housing 31; and the bearing 33 is installed in the housing 31, and two ends of the driving shaft 34 are provided with one bearing 33 separately. Alternatively, the condensation portion 10 is of an integrated barrel structure, the driving portion 30 is installed at a top of the barrel, and the solid arsenic is discharged from a bottom of the barrel.

Alternatively, the driving member 32 is a motor, a hydraulic motor or a rotary cylinder, and the motor, the hydraulic motor or the rotary cylinder is controlled to be started to drive the scraping portion 20 to, rotate through the driving shaft 34. In an alternative embodiment shown in FIG. 1 and FIG. 2, the driving member 32 is a rotary cylinder.

In an exemplary embodiment, as shown in FIG. 1 and FIG. 2, the waste gas processing device includes a sealing flange 40, the housing 31 being connected with the at least one cover plate 17 through the sealing flange 40, and a magnetic fluid 50 for sealing being provided between the housing 31 and the driving shaft 34. Thus, the sealing flange 40 is provided between the driving portion 30 and the condensation portion 10, and the magnetic fluid 50 for sealing is provided between the housing 31 and the driving shaft 34. By dual seal, the toxic waste gas is prevented from spreading into an external environment, so that the embodiment of the waste gas processing device has good use safety.

Some embodiments of the present disclosure provide a vacuum coating system. The vacuum coating system includes a vacuum coating machine and the waste gas processing device. The vacuum coating machine is provided with a waste gas discharge outlet, and an air inlet 12 of the waste gas processing device is communicated with the waste gas discharge outlet. The waste gas processing device is the foregoing waste gas processing device. Thus, the vacuum coating system provided in the present application generates, during the production process of coating a substrate with gallium arsenide, arsenic-containing waste gas, and the air inlet 12 of the waste gas processing device is communicated with the waste gas discharge outlet, so that the waste gas generated by the vacuum coating system is charged into the waste gas processing device, and arsenic is removed and recovered.

Alternatively, the vacuum coating system further includes a filter for removing arsenic, the waste gas treated by the waste gas processing device is charged into the filter, and residual arsenic in the waste gas is further treated, thereby improving the environmental protection performance of the vacuum coating system. In addition, since there is little arsenic treated by the filter, it is unnecessary to frequently replace a filter element, so as to reduce an economic cost of the vacuum coating system for the waste gas processing.

The vacuum coating machine is controlled to stop working for manual replacement of the filter element, so that a labor intensity of a worker is improved, a physical health of the worker is harmed, and a production efficiency of the vacuum coating machine is affected. The vacuum coating system provided in the present application does not need to frequently replace the filter element, thereby improving the production efficiency of the vacuum coating machine, and reducing the economic cost of the vacuum coating system.

Some embodiments of the present application also provide an operation method of the waste gas processing device, for operating the foregoing waste gas processing device. In an exemplary embodiment, the method includes the following steps. In step S1, a temperature of a condensation cavity 11 of a condensation portion 10 is controlled to be lower than a freezing point of arsenic. In step S2, waste gas is charged into the condensation cavity 11 from an air inlet 12 of the condensation portion 10, so that gaseous arsenic in the waste gas comes into contact with an inner wall surface of the condensation cavity 11 and is condensed on the inner wall surface of the condensation cavity 11 to form solid arsenic, and the treated waste gas is discharged out of the condensation cavity 11 from a air outlet 13 of the condensation portion 10. In step S3, a driving portion 30 of the waste gas processing device is controlled to be started to drive a scraping portion 20 to rotate, the scraping portion 20 rotates to scrape off the solid arsenic condensed on the inner wall surface of the condensation cavity 11, and then the solid arsenic is discharged out of the condensation cavity 11 from a discharge port 14 under the action of gravity.

Some embodiments of the waste gas processing device have the advantages as follows. A chemical method does not need to be adopted for removal of arsenic, thereby saving a chemical reagent, and reducing, a consumption of raw materials. It is unnecessary to dismount a condenser for manual removal, thereby reducing a labor intensity of a worker, and shortening a downtime maintenance time. The contact between the worker and arsenic is avoided, thereby improving the use safety of the waste gas processing device. When the waste gas processing device is used in cooperation with the filter, a life of a filter element may be greatly prolonged, thereby reducing a replacement frequency of the filter element of the filter. The sealing performance is good, and the leakage of the waste gas is avoided.

The above is only some embodiments of the present disclosure, not intended to limit the present disclosure. As will occur to those skilled in the art, the present disclosure is susceptible to various modifications and changes, Any modifications, equivalent replacements, improvements and the like made within the spirit and principle of the present disclosure shall fall within the scope of protection of the present disclosure.

What is claimed is:

1. A waste gas processing device, for removing and recovering arsenic in a waste gas, comprising:
a condensation portion, wherein the condensation portion is provided with a condensation cavity, and an air inlet communicated with the condensation cavity, an air outlet communicated with the condensation cavity and a discharge port communicated with the condensation cavity, the condensation portion being configured to cool the waste gas charged into the condensation cavity from the air inlet, so that gaseous arsenic in the waste gas is condensed on an inner wall surface of the condensation cavity by cooling to form solid arsenic; and
a scraping portion, the scraping portion being rotatably provided in the condensation cavity, a partial surface of the scraping portion abutting against the inner wall surface of the condensation cavity, the scraping portion rotating to scrape off the solid arsenic condensed on the inner wall surface of the condensation cavity and a scraped-off solid arsenic being discharged from the discharge port.

2. The waste gas processing device of claim 1, wherein the condensation cavity is cylindrical, the scraping portion is a scraping plate, a length of the scraping plate is equal to a diameter or a radius of the condensation cavity, a thickness of the scraping plate, is equal to a height of the condensation cavity, and at least one breather hole is provided on the scraping plate.

3. The waste gas processing device of claim 1, wherein the discharge port is located at a bottom of the condensation portion in a vertical direction.

4. The waste gas processing device of claim 1, wherein the condensation portion also comprises an overflow cavity, a liquid inlet and a liquid outlet, the overflow cavity and the condensation cavity are provided at an interval, both the liquid inlet and the liquid outlet are communicated with the overflow cavity, and a coolant flows through the liquid inlet, the overflow cavity and the liquid outlet in sequence to control an internal temperature of the condensation cavity.

5. The waste gas processing device of claim 4, wherein the condensation portion comprises:
a barrel; and
two cover plates, the two cover plates covering two ends of the barrel respectively, wherein the condensation cavity is surrounded by the two cover plates and the barrel,
the overflow cavity being formed on the barrel and/or at least one cover plate

6. The waste gas processing device of claim 5, wherein a mounting hole is provided on at least one cover plate, the waste gas processing device further comprises a driving portion, and the driving portion comprises:
a housing , one end of the housing being connected with the condensation portion and located at the mounting hole
a driving member, the driving member being provided at the other end of the housing and connected to the scraping portion through a driving shaft penetrating into the housing; and
a bearing, the bearing being installed in the housing, and two ends of the driving shaft being provided with one bearing separately.

7. The waste gas processing device of claim 6, wherein the waste gas processing device further comprises a sealing flange, the housing being connected with the at least one cover plate through the sealing flange, and a magnetic fluid for sealing being provided between the housing and the driving shaft.

8. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 1.

9. An operation method of a waste gas processing device, for operating the waste gas processing device of claim 1, comprising the following steps:
step S1: controlling a temperature of a condensation cavity of a condensation portion to be lower than a freezing point of arsenic;
step S2: charging waste gas into the condensation cavity from an air inlet of the condensation portion, so that, gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity, and the scraped-off solid arsenic is discharged from a discharge port of the condensation portion.

10. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 2.

11. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 3.

12. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 4.

13. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 5.

14. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 6.

15. A vacuum coating system, comprising:
a vacuum coating machine, wherein the vacuum coating machine is provided with a waste gas discharge outlet; and
a waste gas processing device, an air inlet of the waste gas processing device being communicated with the waste gas discharge outlet, the waste gas processing device being the waste gas processing device of claim 7.

16. An operation method of a waste gas processing device, for operating the waste gas processing device of claim 2, comprising the following steps:
step S1: controlling a temperature of a condensation cavity of a condensation portion to be lower than a freezing point of arsenic;
step S2: charging waste gas into the condensation cavity from an air inlet of the condensation portion, so that gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity , and the scraped-off solid arsenic is discharged from a discharge port of the condensation portion.

17. An operation method of a waste gas processing device, for operating the waste gas processing device of claim 3, comprising the following steps:
step S1: controlling a temperature of a condensation cavity of a condensation portion to be lower than a freezing point of arsenic;
step S2: charging waste gas into the condensation cavity from an air inlet of the condensation portion, so that gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity, and the scraped-off solid arsenic is discharged from a discharge port of the condensation portion.

18. An operation method of a waste gas processing device, for operating the waste gas processing device of claim 4, comprising the following steps:
step S1: controlling a temperature of a condensation cavity of a condensation portion to be lower than a freezing point of arsenic;
step S2: charging waste gas into the condensation cavity from an air inlet of the condensation portion, so that gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity , and the scraped-off solid arsenic is discharged from a discharge port of the condensation portion.

19. An operation method of a waste gas processing device, for operating the waste gas processing device of claim 5, comprising the following steps:
step S1: controlling a temperature of a condensation cavity of a condensation portion to be lower than a freezing point of arsenic;
step S2: charging waste gas into the condensation cavity from an air inlet of the condensation portion, so that gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity , and the scraped-off solid arsenic is discharged from a discharge port of the condensation portion.

20. An operation method of a waste gas processing device, for operating the waste gas processing device of claim 6, comprising the following steps:
step S1; controlling a temperature of a condensation cavity of a condensation portion to be lower than a freezing point of arsenic;
step S2: charging waste gas into the condensation cavity from an air inlet of the condensation portion, so that gaseous arsenic in the waste gas comes into contact with an inner wall surface of the condensation cavity and is condensed on the inner wall surface of the condensation cavity to form solid arsenic; and
step S3: controlling a driving portion of the waste gas processing device to be started, wherein the driving portion drives a scraping portion to rotate, the scraping portion rotates to scrape off the solid arsenic condensed on the inner wall surface of the condensation cavity and the scraped-off solid arsenic is discharged from a discharge port of the condensation portion.
